(19) United States
(12) Patent Application Publication
(10) Pub. No.: US 2003/0085631 A1
(43) Pub. Date: May 8, 2003

(54) Piezo-electric sensor for detecting door opening or closing

(75) Inventors: Leonard Steven Cech, Strongsville, OH (US); Benito Trevino, Lyndhurst, OH (US)

Correspondence Address: Timothy E. Nauman, Esq., Fay, Sharpe, Fagan, Minnich & McKee, LLP, Seventh Floor, 1100 Superior Avenue, Cleveland, OH, 44114-2518, US

(73) Assignee: General Electric Company

(21) Appl. No.: 10/033,053

(22) Filed: Oct. 25, 2001

(51) Int. Cl. H01L 41/113

(52) U.S. Cl. 310/319

(57) ABSTRACT

A sensor system (30) detects the occurrence of angular rotation of a pivotable member (22), such as a door, relative to a fixed member (16), such as the base of a mailbox (10). The sensor system includes a sensor strip (34) positioned so as to change orientation when the door is opened or closed and generate an electrical signal. An RF transmitter (62) signals a receiver (60) at a remote location when the sensor strip registers the opening or closing. A filter (72) filters out noise to inhibit accidental signaling of door opening and/or closing when opening or closing has not occurred. A charge tuner (80) stores charge generated by the piezo-electric element to maintain the transmitter signal beyond the period of opening or closing.

### FIELD OF INVENTION

The present invention relates to a sensor for detecting the opening or closing of a door. More particularly, it relates to a piezo-electric sensor system for detecting and signaling the opening or closing of a hinged mailbox lid, and it will be described with particular reference thereto. It is to be appreciated, however, that the invention is also applicable to the detection of movement of other hinged devices, such as doors, windows, and the like.

### BACKGROUND OF THE INVENTION

For owners of mailboxes which are situated at a remote location from a house or place of business, it is helpful to know when a delivery of mail has been made so that the mailbox owner can retrieve the delivered items.

U.S. Pat. No. 4,872,210 discloses a curbside mailbox detector, which emits a radio signal in response to the closing of a mailbox door. The switch may be a mechanical, gravity actuated, or mercury switch or a photodiode. There are several problems with such switches. First, the mechanical switches work only if the door is closed. If the door is left open after insertion of the mail, the switch does not register the delivery. Mechanical switches generally also require a high degree of specialized alignment and placement precision to operate effectively. The wide range of design considerations for mailbox lids, such as hinge size, spacing, gap width, locking method, and the like, compounds this problem. Also, many mechanical switches are prone to degradation or failed performance due to prolonged environmental exposure. For example water, ice, salt, sun, and the like tend to impair the mechanical switch or render it inoperable. Gravity and mercury switches are not amenable to side opening doors, where the forces of gravity are not applicable. Moreover, mercury is a hazardous material and some states are considering a ban on products that use mercury. Further, switches of the type shown in U.S. Pat. No. 4,872,210 consume a relatively large amount of power.

Piezo-electric materials respond to electric fields by generating mechanical energy. The converse is also true in that materials respond to mechanical energy by generating an electrical signal. Piezo-electric materials have been used extensively as sensors and acoustical/electrical coupling devices. However, such sensors are generally designed to respond to an imposed electric field by a change in configuration of a piezo-electric film. The films may be of different materials including a polymer, such as a polyvinylidene fluoride (PVDF), which are drawn or stretched while subjecting the polymer film to an electric field. U.S. Pat. No. 4,405,402, for example, discloses a thick piezo-electric/pyroelectric element made from polarized plastics such as polyvinylidene fluoride. The piezo-electric film will then respond to applied electrical fields by either lengthening or shortening depending upon the direction of the applied field. There are several techniques for making such sensor-elements using piezo-electric films. A common method involves folding the piezo-electric polymer film in multi-layers using an epoxy resin or a glue as an adhesive between film layers. U.S. Pat. No. 4,417,169, for example, discloses a photoelectric circuit arrangement for driving a piezo-electric bimorph element to bend and thereby to open or close a window blind according to the quantity of transmitted light through the blind. U.S. Pat. No. 4,342,936 discloses a piezo-electric flexure mode device (called a “unimorph”) comprising a layer of piezo-electric active material bonded to a layer of piezo-electric inactive material.

There are several applications for piezo-based switches; however, most of these applications exploit the deflection of the tip of a piezo cantilever element through a small angle (see, for example, U.S. Pat. No. 5,034,648).

The present invention provides a new and improved sensor and methods of preparation and use, which overcome the above-referenced problems, and others.

### SUMMARY OF THE INVENTION

In an exemplary embodiment of the invention, a system for indicating a change in angular position of a pivotable member relative to a fixed member to which the pivotable member is pivotally connected is provided. The system includes a piezo-electric element which generates an electrical signal when the change in angular position occurs. A transmitter transmits a signal in response to the change in angular position to a remote location.

In another exemplary embodiment of the invention, a method of communicating when a pivotable member moves between an open position and a closed position is provided. The method includes positioning a piezo-electric element such that an electrical signal is generated in response to the pivotable member moving between the open and closed positions. A transmitter is activated when the piezo-electric element generates an electrical signal which is above a threshold level, such that the transmitter sends a signal to a receiver at a remote location.

In another exemplary embodiment of the invention, a mailbox and sensor system is provided. The system includes a mailbox and a sensor system which detects at least one of opening and closing of a door to the mailbox. The sensor system includes a piezo-electric element which generates an electrical signal in response to the at least one of opening and closing of the door. A transmitter sends a signal to a remote location when the sensor system detects the at least one of the opening and closing of the door.

One advantage of the present invention is that, unlike gravity switches, the piezo sensor switch can be applied across any arbitrarily oriented 1-degree of freedom hinged element.

Another advantage of the present invention is that the sensor overcomes the need for highly accurate alignments used in other mechanical contact switch technologies.

Another advantage of the present invention derives from the ability of a piezo-film to act as a strong mechanical to electrical converter. This allows the electrical energy from the sensing mechanism to be used to drive or partially drive a remote control circuit, reducing or eliminating the need for replaceable batteries.

### BRIEF DESCRIPTION OF THE DRAWINGS

FIG. 1 is a schematic perspective view of a mailbox and sensor system according to the present invention;

FIG. 2 is a top view of one embodiment of the sensor of FIG. 1 with a mailbox as shown in the open position;

FIG. 3 is a side sectional view of the sensor and mailbox lid and base of FIG. 2,

FIG. 4 is a schematic side sectional view of the mailbox base of FIG. 1 showing the lid and piezo-film functional diagram of piezo-film in open O and closed C positions.

FIG. 5 is a circuit diagram of an actuation system and transmitter of the sensor system of FIG. 1;

FIG. 6 is a plot showing the voltage output of the piezo-electric film during opening and/or closing of the door of FIG. 1;

FIG. 7 is a circuit diagram showing a preferred embodiment of the circuit of FIG. 5;

FIG. 8 is a circuit diagram of a second actuation system and transmitter of the sensor system of FIG. 1;

FIG. 9 is a circuit diagram of a third actuation system and transmitter of the sensor system of FIG. 1;

FIG. 10 is an exemplary embodiment of the third actuation system and transmitter of the sensor system of FIG. 9;

FIG. 11 is a plot of showing the voltage output of an actuation circuit during opening and/or closing of the door prior to inversion;

FIG. 12 is a plot of showing the voltage output of an actuation circuit after inversion;

FIG. 13 is a plot of showing the voltage output of a timer which has converted the signal of FIG. 12 to a single pulse; and

FIG. 14 is a perspective view of a sensor system of the present invention employed in a side opening window.

### DETAILED DESCRIPTION OF THE INVENTION

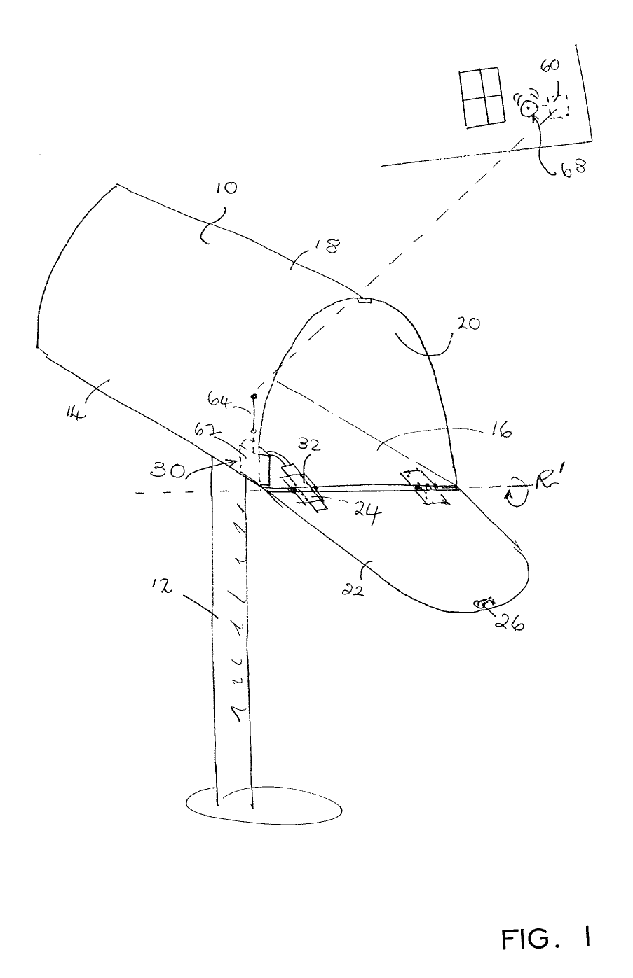

With reference to FIG. 1, a conventional curbside-style mailbox 10 is shown supported on a post 12, or other suitable support. The mailbox includes a box 14 having a generally flat base 16 and a curved top 18, which together define an opening 20. A door or lid 22 is pivotally connected to the box adjacent the base by one or more pivoting members, such as hinges 24. Such boxes are conventional and are subject to considerable variation within the scope of the invention. When the postal worker delivers mail, a catch 26 is released and the door is opened by the postal worker and the mail inserted into the box.

A sensor system 30 detects movement of the door 22 and sends a signal to a remote location, such as the home or business of the mailbox owner. It will be appreciated that the sensor system has numerous other sensor applications, and is also applicable to the sensing and signaling of the opening and/or closing of other pivotable members, such as windows or entry doors to a building or to a room within a building. For example, the sensor may be employed to detect unauthorized entry to a room or building, to record which windows or doors are open, or to track movement into and out of a room or building. The sensor may be linked to a security system of a home or business, which notifies the resident of an intrusion and, if appropriate, alerts a security service of an unauthorized ingress.

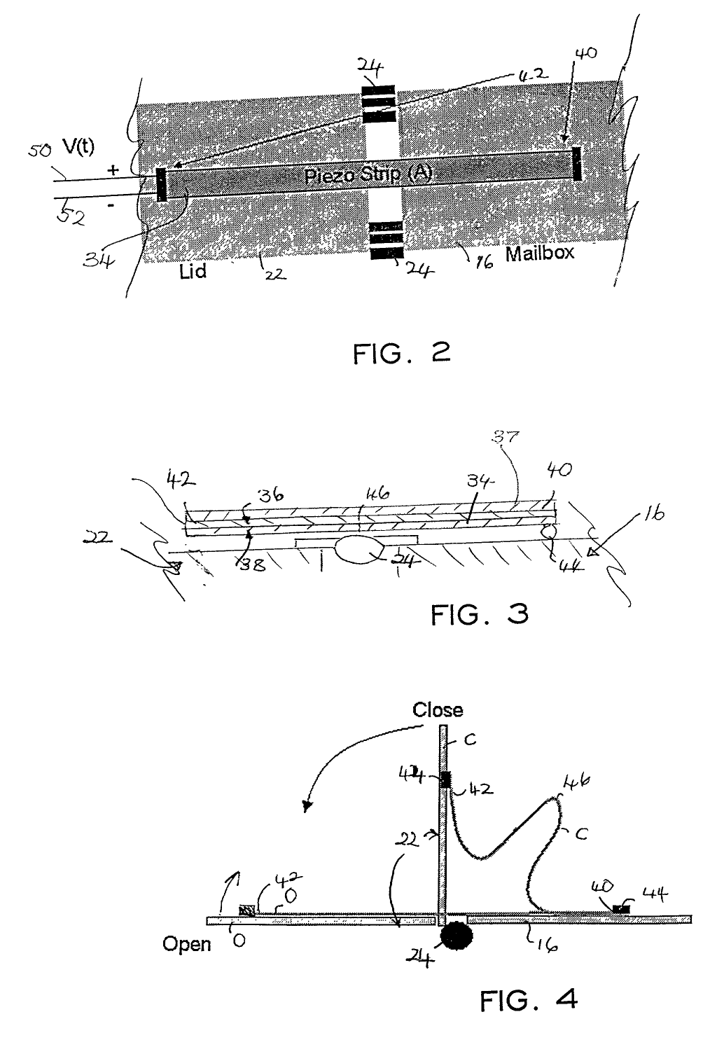

With reference also to FIGS. 2 and 3, the sensor system 30 includes a sensor element 32. The sensor element includes a piezo-electric film, or piezo-film 34, comprising a generally planar layer or membrane 36 of piezo-electric material, which may be laminated to upper and/or lower flexible members 37, 38 to provide support for the film and provide weather protection. In a preferred embodiment, the upper layer 37, and optionally also the lower layer 38, is formed from a resiliently flexible material which filters out light and IR, UV or other stray sources which could activate the piezo-film and lead to inaccurate sensing of door opening/closing. For example, the layers 37, 38 may be formed from a plastic or urethane coating material or other polymeric material. The thickness of the layers is not critical, provided that it allows the piezo-electric layer 36 to flex and return to its original configuration over numerous open/close cycles. A thickness of about 5-20 micrometers (μ) for the layer is suitable, most preferably, about 10μ.

In a preferred embodiment, the piezo-layer 36 is sealed within the laminate layers 37, 38, for example, by heat sealing or otherwise sealing the layers 37, 38 together, around the four edges of the piezo-layer.

The piezo-film 36 may be formed, for example, from a polyvinylidene fluoride (PVDF) material, such as is obtainable from Measurement Specialties Incorporated, and is preferably about 20μ-60μ in thickness, most preferably about 40μ in thickness.

The film is preferably formed from a flexible, durable material that effectively converts mechanical work into electrical impulses. The film provides a passive dual-state sensor switch that indicates the open and/or closed state and/or change of state between the open and closed positions of a lid or door that is hinged to a rigid body, in the exemplary embodiment, the door of a mailbox.

A piezo-ceramic member may also be used as a piezo-strip in place of the laminated polymer film. Alternatively, the piezo-film may be in the form of a cable or as a coating for an extensible member, such as a spring. In this latter embodiment, the piezo-sensor does not bend in the same way as the piezo-strip as the door pivots but is nevertheless subjected to mechanical work which causes an electrical signal to be emitted. For ease of discussion, the piezo-element will be described in terms of the strip, although it will be appreciated that other piezo-elements are also contemplated.

The piezo strip 34 is positioned such that when the door is opened or closed, the film 36 is deflected and creates an electrical impulse as a result. The piezo-film 36 is thus preferably placed across the door rotational axis R¹ (FIG. 1). In one embodiment, the piezo-film is affixed adjacent both sides of the hinge 24 (e.g., attached to the base 16 and door 22 adjacent ends 40, 42, respectively, of the piezo-film, as shown in FIG. 2). In an alternative embodiment, shown in FIG. 3, the film is connected to the mailbox only at one of its ends 40, the other end 42 being free to move as the hinge 24 rotates. Double-sided adhesive tape, glue or other attachment system 44 may be used to attach the piezo-film to the door 22 and/or base 16 (FIG. 3). The center 46 of the piezo-film 34 is preferably positioned approximately mid-way between the two sides of the hinge centered along the axis of rotation R¹ of the hinge and experiences maximum bending when the hinge is opened or closed. When the door is in the closed position, the generally planar piezo-film 36 is bent, as shown at C in FIG. 4. In the absence of stress, i.e., when the door is in the open position, as shown O in FIG. 4, the flexible member returns to a generally two-dimensional linear element.

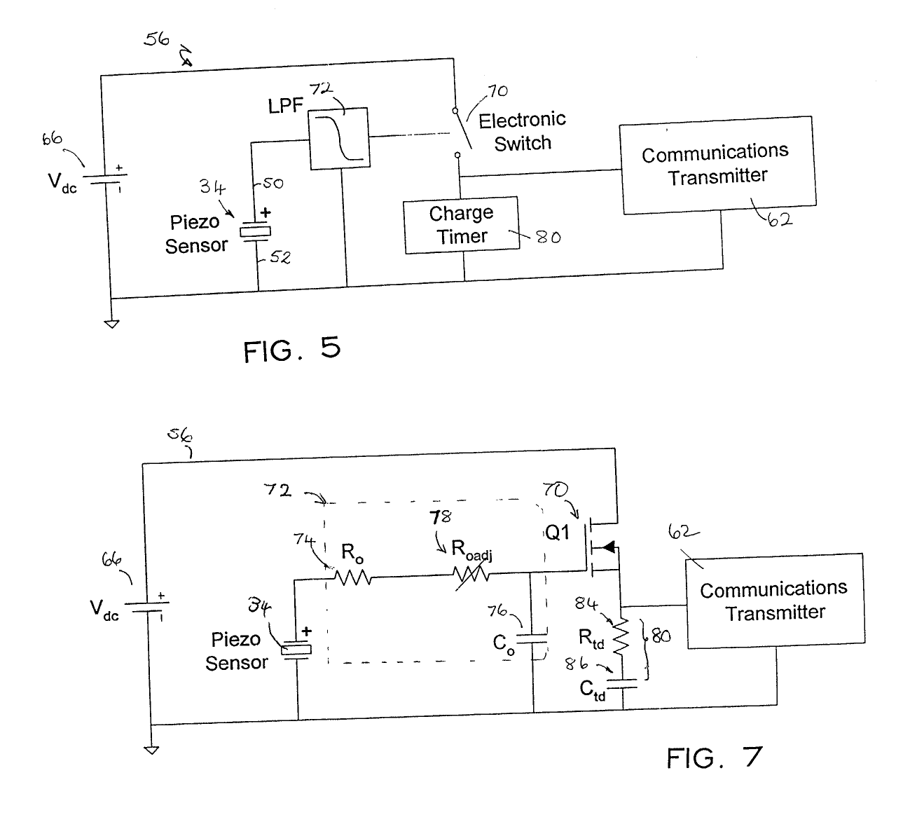

With reference now to FIG. 5, the piezo-film sensor is electrically connected by leads 50, 52 to an actuator circuit 56. The motion of the hinge 24 in opening and/or closing induces a low frequency voltage impulse in the piezo-film (FIG. 6) that is carried by the leads 50, 52 and input into the actuator circuit 56. The circuit 56 preferably includes signal conditioning elements which control a trigger threshold level, delay, and operational time constant of a relay element. The threshold level is preferably set such that electrical “noise” and/or mechanical “noise” due to minor movement of the mailbox, such as due to wind or thermal expansion and contraction, do not activate a signal. The actuator circuit 56 thus preferably blocks all high frequency EMI and vibration induced voltages.

In one embodiment, the circuit 56 is constructed to generate a single output that is held at an output voltage, such as a positive voltage for a pre-determined time when the door 22 has been opened and then returns to zero volts for all other times. It will be appreciated that the circuit could also be constructed to generate an output when the hinge is returned to the closed position (or to generate an output on both opening and closing).

Unlike conventional piezo-based switches, where detection is based on the deflection of the tip of a piezo-cantilever element through a small angle, the present sensor may be positioned and rigidly fixed to the mailbox at one or both ends of the piezo element such that the piezo-element 34 is deflected in the center through a large angle (approximately 90 degrees, or more). Also, in this embodiment, the piezo element is held under stress while the hinge is at 90 degrees (door closed) and allowed to release to it's natural state when the hinge is opened (0 degrees).

When the output voltage exceeds a threshold voltage, this constitutes a change in state of the hinge where the hinge 24 state information is to be communicated to a receiver 60 at the remote location (FIG. 1). A communications transmitter, such an RF remote control transmitter 62 with an antenna 64 sends a signal to the receiver 60 at the remote location indicating that the hinge has been opened. The transmitter 62 may be battery powered or supplied with an AC voltage by a conventional power line.

In one embodiment, the voltage induced by the piezo-film supplies the power for triggering the wireless RF transmitter 62. The transmitter uses power from a battery 66 to transmit the new hinge state information. The voltage induced in the piezo-film may also be used to supply the power to drive the remote control transmitter 62 or to supply some of the power partially driving the circuit 56 that transmits the new hinge state information. The amount of power needed for the RF transmitter is partially dependent on its range, in this case, the distance between the transmitter 62 and receiver 60.

This embodiment takes advantage of the energy conversion properties of the piezo-film to actuate the communications transmitter whenever mechanical motion is detected. For instance, as mechanical energy is incident on the sensor, the voltage produced by piezo-film enables the communications transmitter via the interface circuit 56.

The RF transmitter 62 can be affixed to the door 22 of the mailbox, or as shown in FIG. 1, supported within the mailbox. As the door is opened (or closed), the piezo-film changes mechanical orientation and a potential difference is created across its outer layers. This, in turn, enables the RF transmitter and a signal is communicated to the remote receiver 60 located inside the house or other remote location, which alerts the consumer of ‘incoming mail.’ The remote receiver 60 may signal an alarm or buzzer 68, which generates an audible sound when the signal is transmitted. Alternatively, or additionally, the remote transmitter may be hooked up to a security system or to a computer processing system, which relays the signal to a visual display, such as an LED display screen or to a second remote location.

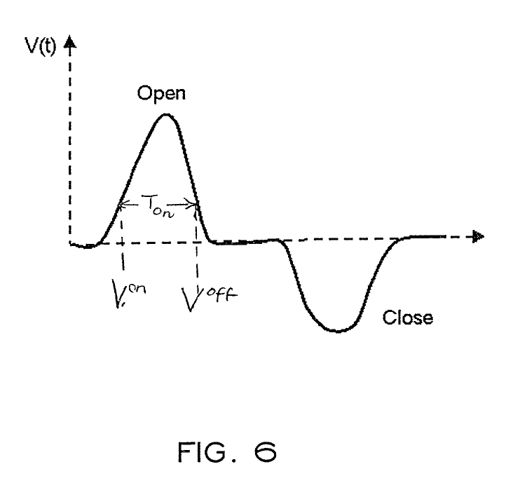

With reference once more to FIG. 5 and reference also to FIG. 7, one configuration of the actuator 56 for the signal transmission is shown. As mechanical energy is incident on the piezo-film sensor, a voltage signal is induced that is used to drive an electronic switch 70, such as a transistor. The voltage signal may contain high frequency parasitic transients that are filtered out by a signal conditioning element or elements, such as low pass filter (LPF) 72. This ensures a smooth profile and prevents ‘noise’ from actuating the electronic switch. Essentially, the LPF serves as a sensitivity tuner whose cut-off frequency determines the quality of the voltage generated signal required to actuate the electronic switch. The lower the cut-off frequency, the more robust the input voltage signal has to be to yield actuation. Thus, the cut-off frequency can be minimized when detecting strong mechanical forces (low sensitivity) or maximized when detecting minute mechanical forces (high sensitivity). The preferred cut-off frequency is thus dependent, to some extent, on the location of the piezo-film and the mechanical forces generated when the door 22 is opened or closed.

The low pass filter 72 may be constructed using a single resistor and capacitor. FIG. 7 illustrates a more preferred low pass filter configuration, consisting of a resistor 74, a capacitor 76 and a variable resistor 78, such as a rheostat or potentiometer. The adjustable resistor allows tuning of the cut-off frequency (sensitivity) via the following relation:

$$sensitivity ∝ {f}_{c} = \frac{1}{( {R}_{o} + {R}_{oadj} ) \cdot {C}_{o}} \qquad ( 1 )$$

where Rₒ denotes the resistance (in Ω) of resistor 74, Cₒ the capacitance (in farads) of a capacitor 76, and R_{oadj} the resistance (in Ω) of adjustable resistor 78, and f_{c} is the cutoff frequency in Hz.

The low pass filtered voltage signal then preferably activates the electronic switch that creates a low impedance current path between the DC supply V_{dc} 66 and both the communications transmitter 62 and an RC charge timer 80. Thus, the communications circuitry is enabled and a transmission ensues. The electronic switch remains on for as long as the filtered voltage signal remains above the device turn-on threshold voltage. The ‘on time’ may be defined as Tₒₙ (e.g. see FIG. 6, V^{o}−V^{off}) and is a function of the mechanical actuation profile. Tₒₙ is preferably maximized for sluggish and minimized for swift mechanical actuation, respectively.

The charge timer 80, where present, stores charge during the Tₒₙ cycle that can maintain the communications transmitter operating after the electronic switch has been turned off. Thus, the transmission window is extended to ensure adequate communication between the transmitter and receiver. A preferred charge timer 80 comprises a series RC circuit including a resistor 84 of resistance R_{td} and a capacitor 86 of capacitance C_{td}. During the Tₒₙ cycle, the capacitor voltage, V_{c}, charges according to the following relation.

$${V}_{c}^{on} ( t ) = {V}_{dc} \cdot ( 1 - {ⅇ}^{\frac{- t}{{R}_{td} {C}_{td}}} ) \qquad ( 2 )$$

where V is in volts and t is the time, in seconds. At the end of the Tₒₙ cycle, the filtered voltage signal incident on the electronic switch falls below the turn-on threshold voltage and the electronic switch is disabled. Thus, the capacitor voltage discharges through the communications transmitter's 62 input resistance, Rᵢₙₚᵤₜ, according to the following relation:

$${V}_{c}^{off} ( t ) = {V}_{dc} \cdot {ⅇ}^{\frac{- t}{{R}_{input} {C}_{td}}} \qquad ( 3 )$$

From the above equations, it is clear that to maximize the communications transmitter “on” time, the discharge time constant Rᵢₙₚᵤₜ·C_{td} should be maximized. Generally, Rᵢₙₚᵤₜ is a characteristic of the communications transmitter and cannot be readily changed. Thus, the capacitor's capacitance C_{td} is preferably maximized while still ensuring that its capacitance is low enough to charge almost completely to V_{dc} during Tₒₙ. Most preferably, C_{td} charges to approximately 90% or more of V_{dc}. Referring to equation 2, it should be noted that V_{c} charges to 90% of V_{dc} when:

t=Tₒₙ=2.3·R_{td}·C_{td} (4)

From the above, assuming Tₒₙ is inherent in the mechanical actuation profile, to maximize C_{td}, R_{td} is minimized. However, it is preferable to ensure that the power rating for R_{td} is not exceeded. Resistor 84 should be able to support a current of V_{dc}/R_{td} at the beginning of Tₒₙ when V_{c} is approximately 0. The following relation illustrates the power dissipated by R_{td}:

$${Power}_{{R}_{td}} = \frac{{V}_{dc}^{2}}{{R}_{td}} \qquad ( 5 )$$

Given that V_{dc} is a constant and, for most purposes, unchangeable (as is the case with a simple battery), a minimum allowable value of R_{td} is arrived at by choosing the desired R_{td} power rating (e.g., 0.25 W). Referring to Equation 4, this leads to a maximum allowable value of C_{td} to ensure nearly full charging during Tₒₙ. This, in turn, leads to a maximum discharge constant and thus a maximum extended transmission window. In other words, the higher the power rating, the lower R_{td}, the higher C_{td}, the higher the discharge time constant Rᵢₙₚᵤₜ·C_{td}, and thus the longer the transmission time. However, the cost of the system significantly increases with increasing power rating. Additionally, the range of the transmitter is also dependent on the power rating. Thus, it is generally desirable for the R_{td} power rating to be about 0.1-0.25 W.

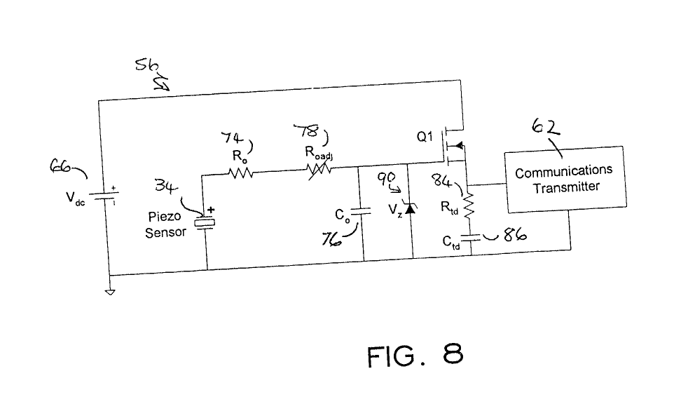

With reference now to FIG. 8, a voltage clamp 90, such as a Zener diode, may be used in the circuit of FIGS. 5 and 7 to clamp the voltage at a maximum set by the selected voltage clamp. The voltage clamp helps to prevent damage to the electronic switch. If a robust electronic switch is used, the voltage clamp is not needed. Additionally, the LPF 72 may be eliminated from the embodiments shown herein if high frequency noise is not a concern. Alternatively, the potentiometer 78 is not required if the sensitivity is fixed.

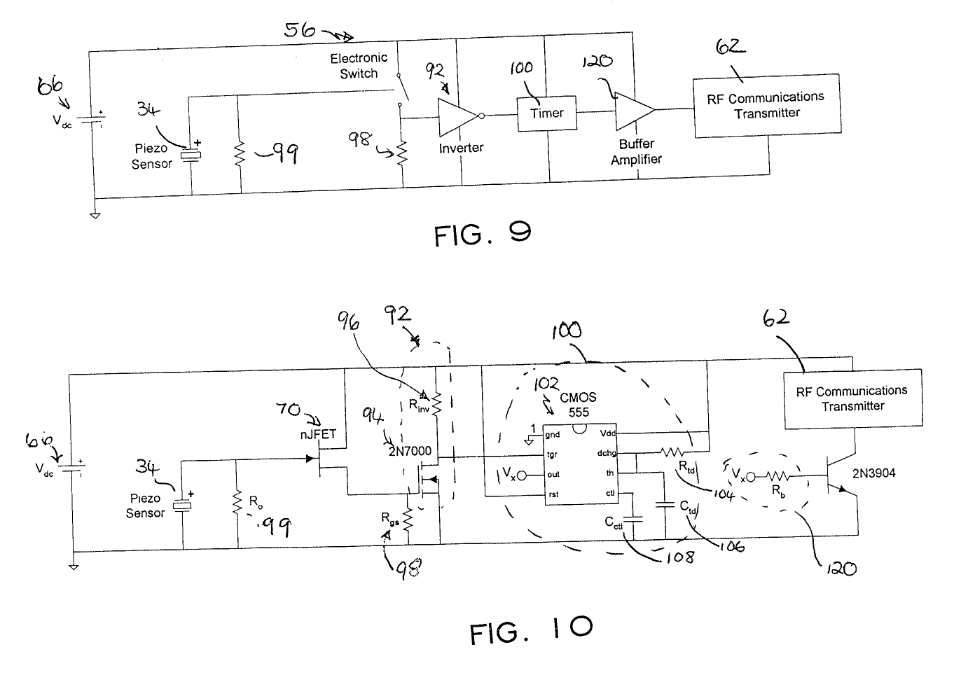

With reference now to FIGS. 9 and 10, another embodiment of a functional diagram for the system is shown. In this embodiment, the opening of the door may cause the output of the piezo-strip to be in the form of one or more voltage peaks, typically of decreasing intensity. The piezo-electric element may be similar to that shown in FIGS. 2-4.

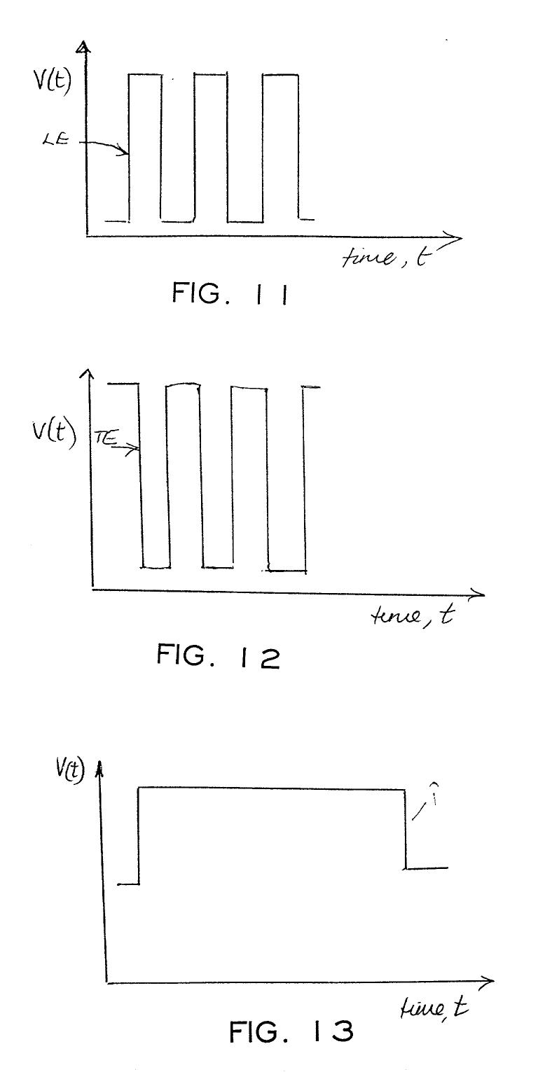

The voltage peak(s) generated by the piezo-electric element actuate the electronic switch, producing an approximate square wave, as shown in FIG. 11. An inverter 92, such as a MOSFET device 94 with a resistor 96, inverts the square wave signal, such that the first peak starts with a negative slope (trailing edge TE) rather than a positive slope (leading edge LE), as shown in FIG. 12. A bleed resistor 98 may be used in association with the inverter to bleed charge present at the MOSFET gate. In this embodiment, the Low Pass Filter 72 is not needed, and can be replaced with, for example, a simple fixed resistor 99. The inverter 92 and electronic switch can be obtained as a single device.

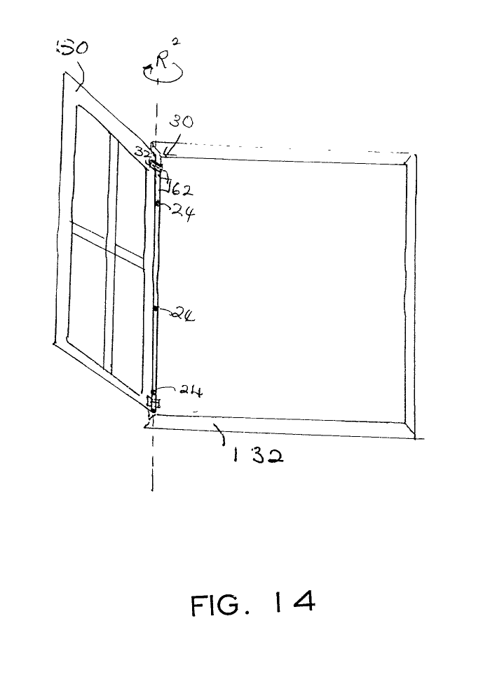

The signal from the inverter is fed to a timer device 100. The timer device signals the transmitter 62 when it receives a signal which is above a threshold level. One suitable timer includes a CMOS or BiCMOS device 102, with associated resistor 104 and capacitors 106, 108, which in this embodiment is a CMOS 555 timer chip, as illustrated in FIG. 10. The CMOS 555 timer draws less than 100 μA in standby mode, which provides extended battery life. The timer 100 recognizes the first trailing edge TE of the inverted signal if it exceeds a threshold (negative) value and generates a single square wave pulse P, as shown in FIG. 13. This pulse P is fed to the communications transmitter 62, optionally via a buffer amplifier 120, which amplifies the signal. For example, the output VₓO from the timer may be several microamps in order to generate a sufficient transmission signal at transmitter 62, the output from the buffer amplifier may be required to amplify this signal and is about 100 microamps, or more. If a BiCMOS timer chip or other higher output device is used in place of a CMOS as shown, the buffer amplifier may be eliminated. Similarly, the buffer amplifier is not needed if the transmitter has a low operating current.

The inverter 92 and timer 100 thus act as a more sophisticated signal conditioning circuit than the low pass filter 72 of the embodiment of FIGS. 5, 7, and 8. As with the embodiments of FIGS. 5 and 7, a charge timer 104, 105 may be incorporated into the timer of FIGS. 9 and 10 for supplying some or all of the power used to operate the actuation circuit 56 and/or transmitter 62.

The advantage of using the inverter 92 is that commercially available timers tend to recognize a trailing edge TE (FIG. 12), rather than a leading edge LE (FIG. 11). It will be appreciated that if a timer 100 which is capable of recognizing a leading edge is used, the inverter can be eliminated. The inverter could also be eliminated if the timer is capable of detecting the trailing edge of the first peak of FIG. 11. This may result in a short (i.e., seconds or less) delay in the signal being transmitted. For many purposes, this delay is not critical.

As will be appreciated, the electronic components, such as switch 70, inverter 92, and timer 100 could all be laid down on a single semiconductor substrate. In this embodiment, the nJFET switch 70 can be eliminated since the 2N 7000 inverter 94 employed also acts as a switch.

As will be appreciated, the sensor is not limited to uses in which gravity acts on the hinge (i.e., the hinge axis of rotation is perpendicular to the forces of gravity, as shown in FIG. 1). Both vertical and horizontal axis of rotation applications is contemplated. For example, FIG. 14 shows a sensor system 30 installed on a hinged window 130, in which the axis of rotation R² is generally vertical. The window is pivotally connected by hinges 24 to a window frame 132.

Another use for the sensor is in the detection of opening and closing of garage doors, such as those of the up-and-over type. In such an embodiment, the panels of the door pivot as they follow tracks on either side of the door. The panels thus change from a vertical to a generally horizontal position as the door opens. At a given time, one of the panels is pivoting with respect to an adjacent panel (the “fixed” member). A piezoelectric strip of the type described herein can be located so as to detect this relative pivoting movement. For example, the strip may be positioned across the gap between the panels so that it is bent as the pivoting panel changes orientation with respect to the other panel.

As will be appreciated, the sensor strip 32 may be positioned anywhere along the axis of rotation R₁, R₂, and need not be directly adjacent the hinge.

As will be appreciated, more complex circuitry may be provided while remaining within the scope of the invention. For example, an amplifier component may be provided for increasing the signal strength from the piezo-film. Additional signal processing/conditioning elements may be provided. A temperature compensation element may also be included which compensates for the effects of changes in the piezo-film due to changes in ambient temperature.

While the invention has been described with respect to specific embodiments by way of illustration, many modifications and changes will occur to those skilled in the art. It is, therefore, to be understood that the appended claims are intended to cover all such modifications and changes as fall within the true spirit and scope of the invention.

What is claimed is:

1. A system for indicating a change in angular position of a pivotable member relative to a fixed member to which the pivotable member is pivotally connected, the system including:
a piezo-electric element which generates an electrical signal when the change in angular position occurs; and
a transmitter for transmitting a signal in response to the change in angular position to a remote location.

2. The system of claim 1, wherein the piezo-electric element comprises a strip, which is attached adjacent one of first and second ends thereof to one of the pivotable member and the fixed member.

3. The system of claim 2, wherein the strip is attached adjacent the first end to the pivotable member and adjacent the second end to the fixed member.

4. The system of claim 1, wherein the pivotable member is a door, which is hingedly attached to the fixed member.

5. The system of claim 4, wherein the fixed member includes a mailbox.

6. The system of claim 1, further including an actuation circuit which activates the transmitter to transmit the signal when it receives an electric signal from the piezo-electric element which is above a threshold level.

7. The system of claim 6, wherein the actuation system includes a conditioning element which filters out electrical signals from the piezo-electric element which are below the threshold level.

8. The system of claim 7, wherein the signal conditioning element includes a capacitor and a resistor.

9. The system of claim 8, wherein the signal conditioning element further includes an adjustable resistor.

10. The system of claim 7, wherein the signal conditioning element includes a timer which generates a single voltage pulse when the piezoelectric element generates a signal which is above the threshold level.

11. The system of claim 10, further including an inverter which inverts the signal generated by the piezo-electric element, the timer recognizing a trailing edge of a voltage peak generated by the inverter.

12. The system of claim 1, wherein the actuation system includes a charge timer which stores a charge when the piezo-electric element generates the electrical signal.

13. The system of claim 12, wherein the charge timer supplies at least a portion of power used by the transmitter.

14. The system of claim 6, further including a source of electrical power electrically connected with the actuation circuit.

15. The system of claim 6, wherein the actuation circuit includes an electronic switch, the actuation circuit driving the switch to complete an electrical circuit between the actuation circuit and the transmitter when the signal is above the threshold level.

16. The system of claim 1, further including a receiver at a remote location which receives the signal from the transmitter.

17. The system of claim 1, wherein the piezoelectric element generates the electrical signal when it changes its orientation in response to the change in angular position of the pivotable member.

18. A method of communicating when a pivotable member moves between an open position and a closed position, the method comprising:
positioning a piezo-electric element such that an electrical signal is generated in response to the pivotable member moving between the open and closed positions; and
activating a transmitter when the piezo-electric element generates an electrical signal which is above a threshold level, such that the transmitter sends a signal to a receiver at a remote location.

19. The method of claim 18, further including storing an electric charge generated by the piezo-electric element and using the charge to operate the transmitter.

20. A mailbox and sensor system comprising:
a mailbox;
a sensor system which detects at least one of opening and closing of a door to the mailbox, the sensor system including a piezo-electric element which generates an electrical signal in response to the at least one of opening and closing of the door; and
a transmitter for sending a signal a remote location when the sensor system detects the at least one of the opening and closing of the door.
